(19) United States
(12) Patent Application Publication
(10) Pub. No.: US 2006/0126315 A1
(43) Pub. Date: Jun. 15, 2006

(54) Electrical circuit interface board for connecting fuel cell

(76) Inventors: Hsi-Ming Shu, Sin Jhuang (TW); Feng-Yi Deng, Taipei (TW); Tsang-Ming Chang, Taipei (TW); Wei-Li Huang, Taipei (TW); Yu-Lin Tang, Jhong-Ho (TW); Yu-Chin Wang, Tainan (TW); Chien-Lang Wang, Panchiao (TW)

Correspondence Address: G. LINK Co., LTD, 3550 Bell Road, MINOOKA, IL, 60447, US

(21) Appl. No.: 11/298,459

(22) Filed: Dec. 12, 2005

(30) Foreign Application Priority Data
Dec. 13, 2004 (TW) 093220060

(51) Int. Cl. H05K 7/06

(52) U.S. Cl. 361/760

(57) ABSTRACT

An electrical circuit interface board for connecting a fuel cell is described, which includes a substrate, an electrical circuit, a first interface, and a second interface. The electrical circuit is disposed on the substrate. The first interface is disposed on the substrate for electrically connecting the fuel cell, and is electrically connected to the electrical circuit. The second interface is disposed on the substrate for electrically connecting an electrical device, and is electrically connected to the electrical circuit. It becomes feasible to manage the fuel cell through the electrical circuit interface board.

### FIELD OF THE INVENTION

The present invention relates to an electrical circuit interface board, and more particularly, to an electrical circuit interface board for connecting a fuel cell.

### BACKGROUND OF THE INVENTION

Nowadays, technology in the fuel cell domain emphasizes on developing membrane electrode assembly (MEA) and related components thereof to improve efficiency of power generation in MEA. However, the prior arts usually fail to improve the quality of power generation by management in a fuel cell or by providing a power supply capable of managing energy therein.

An electrical circuit interface board for connecting a fuel cell is thus disclosed by the applicant to overcome the aforesaid disadvantages. Hence, it is more practical to manage a fuel cell.

### SUMMARY OF THE INVENTION

It is a primary object of the invention to provide an electrical circuit interface board for connecting a fuel cell, by which management of the fuel cell is easily performed.

In accordance with the object of the invention, an electrical circuit interface board for connecting a fuel cell is provided. The electrical circuit interface board includes a substrate, an electrical circuit disposed on the substrate, a first interface disposed on the substrate for electrically connecting a fuel cell, wherein the first interface is electrically connected to the electrical circuit, and a second interface is disposed on the substrate for electrically connecting an electrical device, wherein the second interface is electrically connected to the electrical circuit.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 illustrates the structure of an electrical circuit interface board for connecting a fuel cell according to one embodiment of the present invention; and

FIG. 2 is a state diagram where an electrical circuit interface board connected between a fuel cell and an electrical device is in use according to one embodiment of the invention.

### DETAILED DESCRIPTION OF THE INVENTION

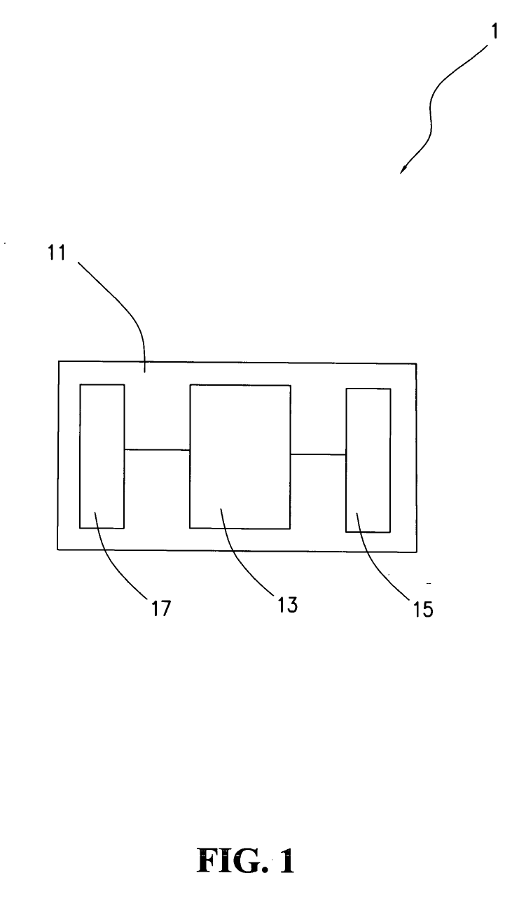

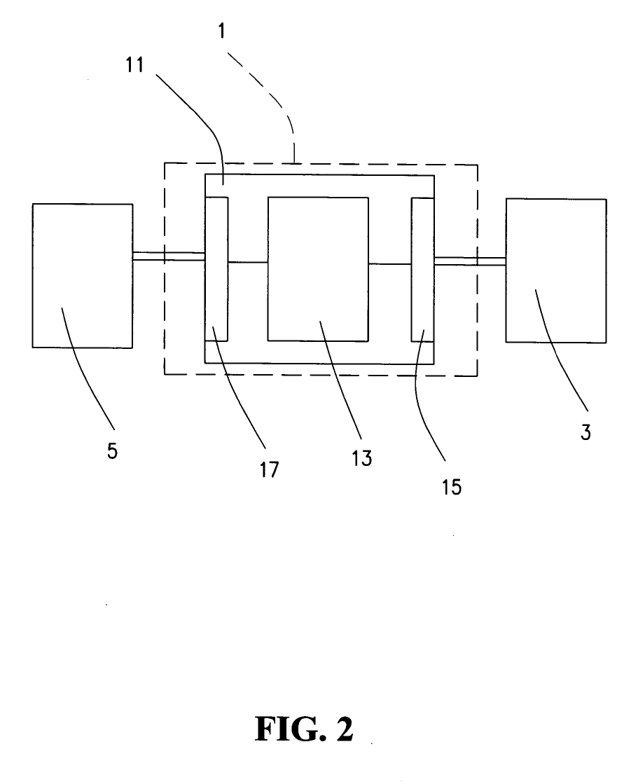

FIG. 1 shows the structure of an electrical circuit interface board for connecting a fuel cell according to one embodiment of the invention. FIG. 2 illustrates the use status of an electrical circuit interface board connected between a fuel cell and an electrical device according to one embodiment of the invention. The electrical circuit interface board 1 comprises a substrate 11, an electrical circuit 13, a first interface 15, and a second interface 17, which are individually described hereinafter. The substrate 11 may be a printed circuit board (PCB) that is fabricated, for example, by etching copper foil to form the layout of the electrical circuit 13 with a PCB process, and then by performing a solder process on electrical devices. In one embodiment, the electrical circuit 13 is an energy-managing circuit for administering the power generation efficiency of the fuel cell 3. In another embodiment, the electrical circuit 13 is a voltage-regulating circuit for converting power generated from the fuel cell 3 into a constant output voltage. In still another embodiment, the electrical circuit 13 is a test circuit for examining the fuel cell 3 and checking the performance thereof or quality of supplied power. In yet another embodiment, the electrical circuit 13 is a signal-transmitting circuit for communication of fuel cells.

The first interface 15 is mainly used to electrically couple the electrical circuit 13 and the fuel cell 3. The first interface 15 comprises, for instance, a cable having two ends soldered to the electrical circuit 13 and the fuel cell 3, respectively. Alternatively, the first interface 15 may be a plug connector that is plugged into the fuel cell 3 directly so that the electrical circuit interface board 1 and the fuel cell 3 are connected to each other. Or, the first interface 15 may be a cable having a connector. The connector at one end of the cable is connected to the fuel cell 3, and the other end of the cable is soldered on the substrate 11.

The second interface 17 is primarily used to electrically connect the electrical circuit 13 and the electrical device 5. The second interface 17 may serve to transfer and supply the power of the fuel cell 3 or the power processed by the electrical circuit 13 for computers or other electrical equipment like devices with processors, or may serve to transfer signals relevant to the fuel cell 3, which is collected by the electrical circuit 13, into some components like test devices 5 for testing fuel cells, or may serve to communicate the electrical circuit 13 and the electrical device 5. In addition, the electrical device 5 can immediately identify the status of the fuel cell 3 through the communication of the first interface 15. The second interface 17 is, for example, a connector, a golden finger, a cable, and so on.

The electrical circuit interface board 1 can be applied to any kind of fuel cell, such as fuel cells with methanol fuels, or fuel cells with liquid fuels, gaseous fuels or solid fuels.

The electrical circuit interface board of the invention possesses some advantages and dominant improvements, which are summarized as follows:
1. Since the electrical circuit interface board is connected between the fuel cell and the electrical device, the fuel cell is capable of communicating with the external environment and is also of greater value; and
2. It is flexible for the electrical circuit interface board to be applied to all kinds of fuel cells.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. An electrical circuit interface board for connecting a fuel cell, with the interface board comprising:
a substrate;
an electrical circuit disposed on said substrate;
a first interface disposed on said substrate and electrically connected to a fuel cell, wherein said first interface is electrically connected to said electrical circuit; and
a second interface disposed on said substrate and electrically connected to an electrical device, wherein said second interface is electrically connected to said electrical circuit.

2. The electrical circuit interface board for connecting a fuel cell of claim 1, wherein said substrate is a printed circuit board.

3. The electrical circuit interface board for connecting a fuel cell of claim 1, wherein said electrical circuit comprises at least an electrical component.

4. The electrical circuit interface board for connecting a fuel cell of claim 1, wherein said first interface is a cable having two ends separately soldered to said substrate and said fuel cell.

5. The electrical circuit interface board for connecting a fuel cell of claim 1, wherein said first interface is a plug connector plugged into said fuel cell.

6. The electrical circuit interface board for connecting a fuel cell of claim 1, wherein said first interface comprises a cable with a connector.

7. The electrical circuit interface board for connecting a fuel cell of claim 1, wherein said electrical device is selected from a group consisting of a computer, a test device for testing the fuel cell, and an electrical device having a processor.
